(19) United States
(12) Patent Application Publication
(10) Pub. No.: US 2012/0108073 A1
(43) Pub. Date: May 3, 2012

(54) METHOD FOR FABRICATING SEMICONDUCTOR DEVICE

(76) Inventors: Hae-Jung LEE, Gyeonggi-do (KR); Eun-Mi Kim, Gyeonggi-do (KR); Kyung-Bo Ko, Gyeonggi-do (KR)

(21) Appl. No.: 12/981,983

(22) Filed: Dec. 30, 2010

(30) Foreign Application Priority Data
Oct. 29, 2010 (KR) 10-2010-0106926

(51) Int. Cl. H01L 21/3065

(52) U.S. Cl. 438/719; 257/E21.218

(57) ABSTRACT

A method for fabricating a semiconductor device includes forming a plurality of patterns, forming an etch target layer to gap-fill the plurality of patterns, forming an impurity region in the etch target layer, and performing an etch-back process on the etch target layer using the impurity region as an etch stop barrier.

### CROSS-REFERENCE TO RELATED APPLICATIONS

The present application claims priority of Korean Patent Application No. 10-2010-0106926, filed on Oct. 29, 2010, which is incorporated herein by reference in its entirety.

### BACKGROUND OF THE INVENTION

Exemplary embodiments of the present invention relate to a method for fabricating a semiconductor device, and more particularly, to a method for fabricating a semiconductor device with appropriate etch uniformity.

In fabricating a semiconductor device, the semiconductor device may include a plurality of patterns having different critical dimensions (“CDs”). In an etching process for forming the patterns having different CDs, specifically a plasma etching process, micro-loading may occur. Micro-loading is a phenomenon where an etched amount (for example, in depth) of a first pattern having a large CD is larger than that of a second pattern having a small CD.

The micro-loading due to a difference in CDs affects subsequent processes. More specifically, after an etch target layer is formed to gap-fill the patterns and an etch-back process of the etch target layer is performed by using a plasma, there may occur a difference in etched amounts of the etch target layer. Here, in the etch-back process, the difference between etched amounts of the etch target layer occurs due to micro-loading. Particularly, the etched amount of the etch target layer in case of the first pattern having the large CD is larger than that of the second pattern having the small CD.

Etch uniformity greatly affects to the characteristic of the semiconductor device. Therefore, obtaining etch uniformity for patterns having different CDs is useful.

### SUMMARY OF THE INVENTION

An embodiment of the present invention is directed to a method for fabricating a semiconductor device to obtain an appropriate etch uniformity while an etch-back process is performed by using a plasma.

In accordance with an embodiment of the present invention, a method for fabricating a semiconductor device includes forming a plurality of patterns, forming an etch target layer to gap-fill the plurality of patterns, forming an impurity region in the etch target layer, and performing an etch-back process on the etch target layer using the impurity region as an etch stop barrier.

In accordance with another embodiment of the present invention, a method for fabricating a semiconductor device includes: forming a plurality of patterns, forming an etch target layer to gap-fill the plurality of patterns, forming a first impurity region in the etch target layer, performing a first etch-back process on the etch target layer using the first impurity region as a first etch stop barrier, forming a second impurity region in the remaining etch target layer, and performing a second etch-back process on the remaining etch target layer using the second impurity region as a second etch stop barrier.

In accordance with yet another embodiment of the present invention, a method for fabricating a semiconductor device includes: forming a plurality of patterns, forming a polysilicon layer to gap-fill the plurality of patterns, forming a P-type impurity region in the polysilicon layer, and performing a plasma etch-back process on the polysilicon layer using the P-type impurity region as an etch stop barrier.

### BRIEF DESCRIPTION OF THE DRAWINGS

FIGS. 1A to 1D are cross-sectional views illustrating a method for fabricating semiconductor device in accordance with a first embodiment of the present invention.

FIGS. 2A to 2F are cross-sectional views illustrating a method for fabricating semiconductor device in accordance with a second embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

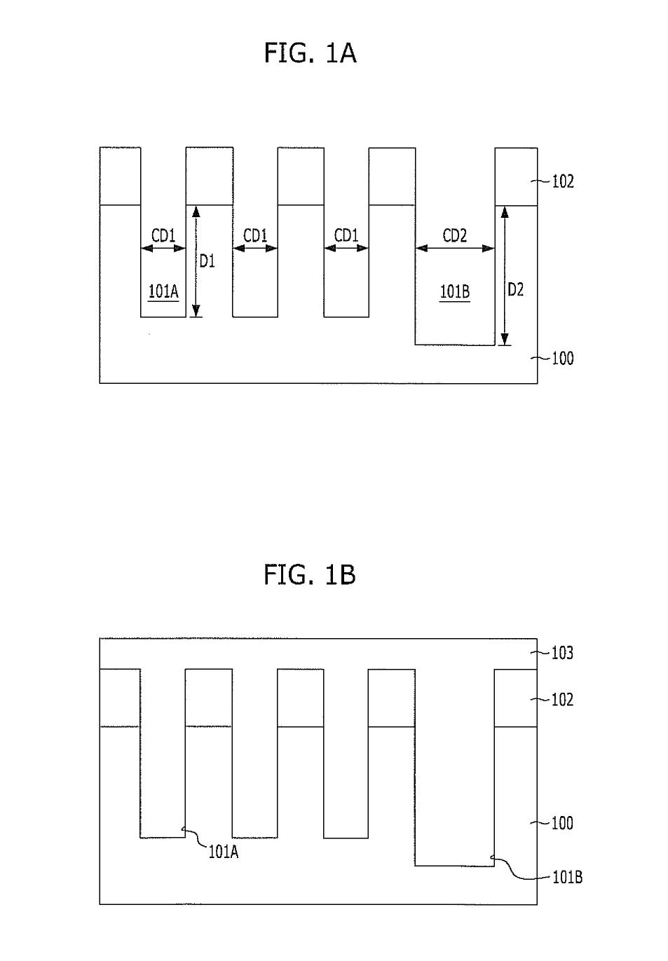

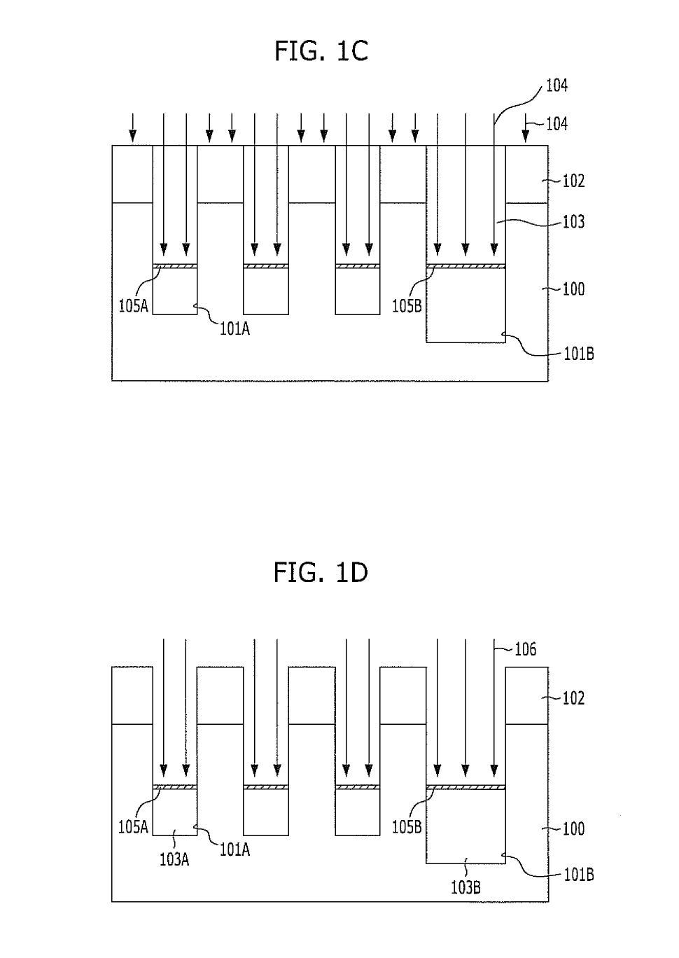

FIGS. 1A to 1D are cross-sectional views illustrating a method for fabricating semiconductor device in accordance with a first embodiment of the present invention.

Referring to FIG. 1A, a plurality of patterns are formed by performing an etch process to a substrate 100. Here, the patterns include trenches and contact holes. The substrate 100 may be any reasonably suitable substrate including a silicon substrate, a polysilicon layer, an insulation layer and a metal layer. The plurality of patterns may have different widths and different depths. Alternatively, the plurality of patterns may have the same width and the same depth.

Hereinafter, the plurality of patterns having different widths and different depths are explained in the first embodiment of the present invention. The plurality of patterns include a first pattern 101A having a first critical dimension CD1 and a second pattern 101B having a second critical dimension CD2. The CD2 is larger than the CD1. Micro-loading occurs when the first pattern 101A and the second pattern 101B are formed under the same etching conditions. Since the etched amount of the second pattern 101B is larger than that of the first pattern 101A in depth, a second depth D2 of the second pattern 101B is larger than a first depth D1 of the first pattern 101A.

The first pattern 101A and the second pattern 101B are formed by a plasma etch process using a plasma. When the substrate 100 is the silicon substrate or the polysilicon layer, the plasma etch process uses the plasma including a halogen such as chlorine (Cl), bromine (Br) or fluorine (F).

A hard mask 102 is used as an etch barrier to form the first pattern 101A and the second pattern 101B. The hard mask 102 is patterned by using a photolithograph process of a photoresist (not shown). The hard mask 102 may be used as an ion implantation barrier while a subsequent ion implantation process is performed.

The material of the hard mask 102 is selected depending on the material of the substrate 100. When the substrate 100 is a silicon substrate or a polysilicon layer, the hard mask 102 may be formed of an amorphous carbon, a nitride material or an oxide material.

Also, the subsequent ion implantation process affects the hard mask 102, and thus, the thickness of the hard mask 102 is to be sufficiently large to prevent the ion implantation onto the substrate 100 through the hard mask 102. Therefore, the hard mask 102 may prevent the ion implantation onto the surfaces of the substrate 100 other than in areas for the first pattern 101A and the second pattern 101B during the ion implantation process. Here, any active region of the substrate is prevented from the impurity implantation.

Referring to FIG. 1B, an etch target layer 103 is formed over the resultant structure including the first pattern 101A, the second pattern 101B and the hard mask 102. The etch target layer 103 may be formed of a conductive material, a metal or a dielectric material.

According to an example, the etch target layer 103 is formed of a silicon layer. The etch target layer 103 is formed of a polysilicon layer. Particularly, the polysilicon layer may include an N-type impurity doped polysilicon layer or an undoped polysilicon layer. Since an N-type impurity may include phosphorus (P) and arsenic (As), an etch selectivity may be maximized when the plasma etch-back process is subsequently performed.

The etch target layer 103 is formed to gap-fill the first pattern 101A and the second pattern 101B. When the substrate 100 is the silicon substrate and the etch target layer 103 is the polysilicon layer, an insulation layer formed of an oxide material or a nitride material may be formed over the substrate 100 before the etch target layer 103 is formed. Although not shown in FIG. 1B, a planarization process may be further performed on the etch target layer 103 so that the etch target layer 103 remains, for example, within the first pattern 101A and the second pattern 101B only.

Referring to FIG. 1C, an ion implantation process 104 is performed. Since the hard mask 102 is used as an ion implantation barrier, the ion implantation process 104 is performed on the etch target layer 103 formed in the first pattern 101A and the second pattern 101B. That is, the hard mask 102 may prevent the ion implantation process 104 on the surfaces of the substrate 100 other than areas of the first pattern 101A and the second pattern 101B. The ion implantation process 104 is performed to implant impurities to a desired depth. Also, the implantation energy of the ion implantation process 104 is adjusted in order that the surfaces of the substrate 100 below the hard mask 102 are not implanted.

Impurity regions 105A and 105B having a desired depth (that is, a desired range of projection (Rp)) are formed in the etch target layer 103 by the ion implantation process 104. Regions above or below the impurity regions 105A and 105B in the etch target layer 103 are not subjected to ion-implantation, where the impurity regions 105A and 105B lie at a depth which is greater than the thickness of the hard mask 102 as shown in FIG. 1C. The depth (Rp) of the first impurity region 105A formed in the first pattern 101A is the same as that of the second impurity region 105B formed in the second pattern 101B.

A thermal treatment process may be further performed to activate the impurities implanted by the ion implantation process 104. Thus, the first impurity region 105A and the second impurity region 105B may be uniformly formed.

When the etch target layer 103 is an undoped polysilicon layer or an N-type impurity doped polysilicon layer, P-type impurities are implanted during the ion implantation process 104. The P-type impurities include boron. A doping source of the P-type impurities may include B and BF₂. The impurity regions 105A and 105B include a P-type impurity doped polysilicon layer. A dopant dose of the ion implantation process 104 ranges from approximately 2×10¹⁵ atoms/cm² to approximately 1×10¹⁷ atoms/cm². Also, as the dopant dose of the ion implantation process 104 is increased, the function of the impurity regions 105A and 105B as the etch stop barrier gets stronger.

Here, according to an example, when the etch target layer 103 is the N-type impurity doped polysilicon layer, a part of the N-type impurity doped polysilicon layer is changed into the P-type impurity doped polysilicon layer by performing the ion implantation process 104.

Referring to FIG. 1D, a plasma etch process 106 is performed to the etch target layer 103 (that is, 103A and 103B). The plasma etch process 106 may include an etch-back process. The plasma etch process 106 of the etch target layer 103 is stopped at the impurity regions 105A and 105B. Then, parts of the etch target layer 103 below the impurity regions 105A and 105B remain as etch target patterns 103A and 103B.

When the etch target layer 103 is the N-type impurity doped polysilicon layer and the impurity regions 105A and 105B are the P-type impurity doped polysilicon layer, the plasma etch process 106 is performed by using the plasma including a halogen such as chlorine (Cl), bromine (Br) or fluorine (F).

While the plasma etch process 106 is performed, etching rate of the etch target layer 103 formed in the second pattern 101B is faster than that of the etch target layer 103 formed in the first pattern 101A due to the larger width of the second pattern 101B. However, the etching rate of the N-type impurity doped polysilicon layer is different that of the P-type impurity doped polysilicon layer. The etching rate of the N-type impurity doped polysilicon layer may be at least two times faster than that of the P-type impurity doped polysilicon layer. That is, the N-type impurity doped polysilicon layer may be selectively etched by using the P-type impurity doped polysilicon layer as an etch stop barrier. Therefore, etch uniformity of the etch target patterns 103A and 103B may be secured. Specifically, the etch target patterns 103A and 103B may be secured although the first pattern 101A and the second pattern 101B have different widths and different depths.

In accordance with the above-described first embodiment of the present invention, the plasma etch process 106 is performed uniformly because the etch process is stopped at the impurity regions 105A and 105B. Although micro-loading tends to increase the etching rate of the etch target layer 103 formed in the second pattern 101B compared to that of the etch target layer 103 formed in the first pattern 101A, the etch target layer 103 is uniformly etched by using the impurity regions 105A and 105B as the etch stop barrier.

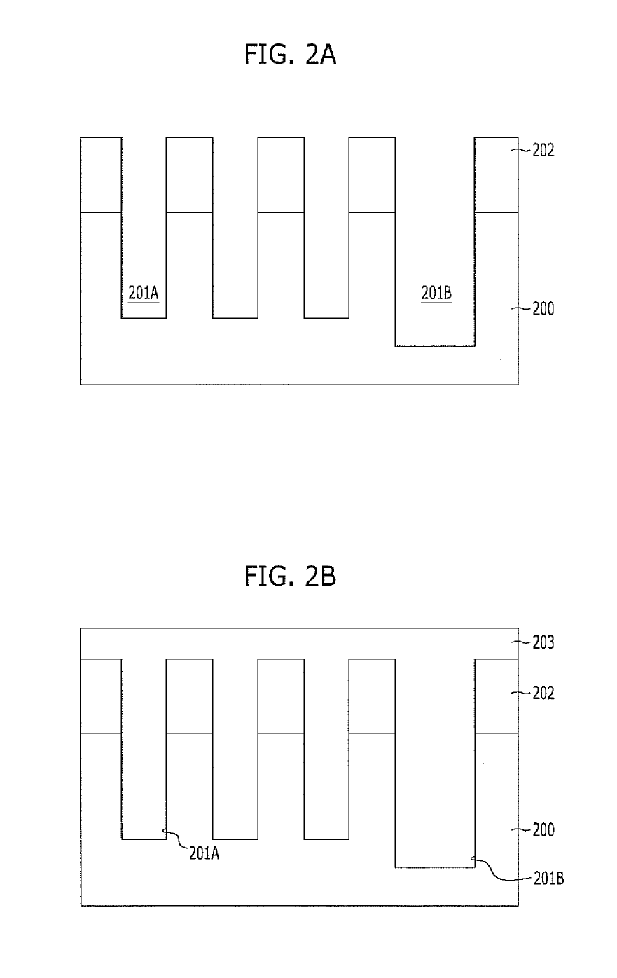

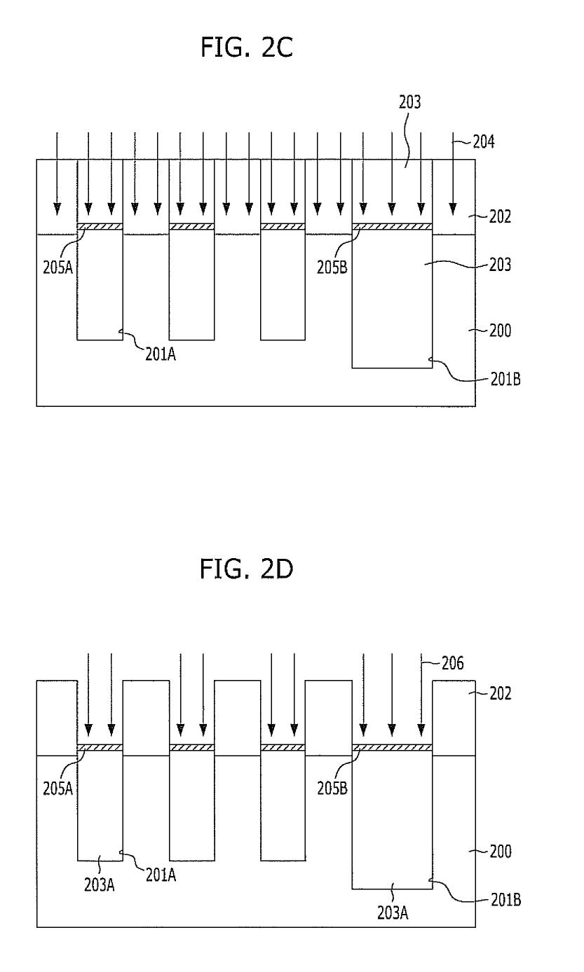

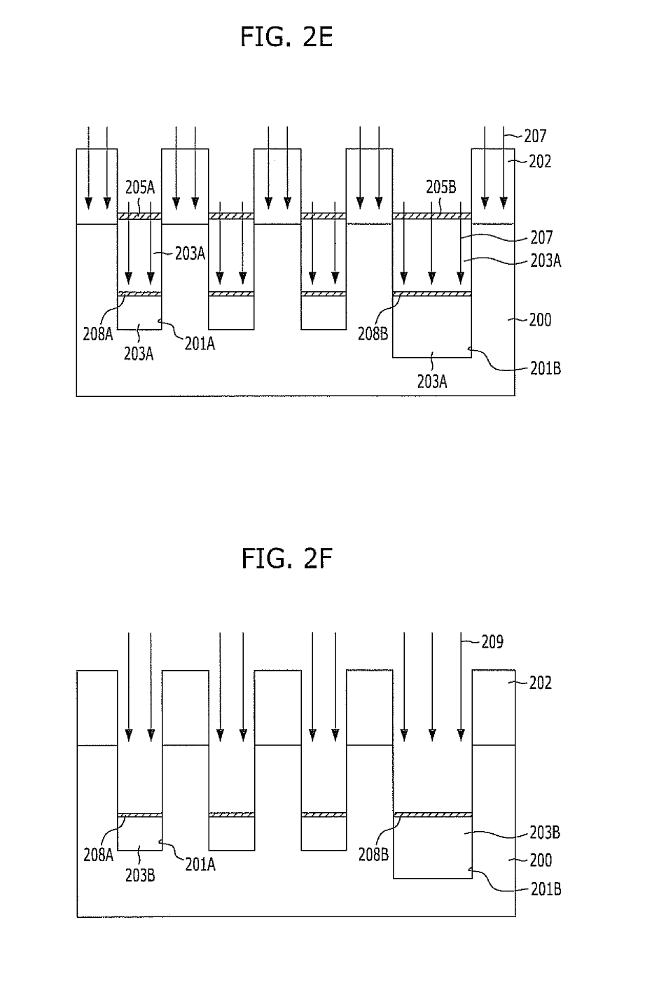

FIGS. 2A to 2F are cross-sectional views illustrating a method for fabricating semiconductor device in accordance with a second Is embodiment of the present invention.

Referring to FIG. 2A, a plurality of patterns are formed by performing an etch process to a substrate 200. Here, the patterns include trenches and a contact holes. The substrate 200 may be any reasonably suitable substrate including a silicon substrate, a polysilicon layer, an insulation layer and a metal layer. The plurality of patterns may have different widths and different depths. Alternatively, the plurality of patterns may have the same width and the same depth.

Hereinafter, the plurality of patterns having different widths and different depths are explained in the second embodiment of the present invention. The plurality of patterns include a first pattern 201A having a first critical dimension CD1 and a second pattern 201B having a second critical dimension CD2. The CD2 is larger than the CD1. Micro-loading occurs when the first pattern 201A and the second pattern 201B are formed under the same etching conditions. Since the etched amount of the second pattern 201B is larger than that of the first pattern 201A, a depth of the second pattern 201B is larger than a depth of the first pattern 201A.

The first pattern 201A and the second pattern 201B are formed by a plasma etch process using a plasma. When the substrate 200 is the silicon substrate or the polysilicon layer, the plasma etch process uses the plasma including a halogen such as chlorine (Cl), bromine (Br) or fluorine (F).

A hard mask 202 is used as an etch barrier to form the first pattern 201A and the second pattern 201B. The hard mask 202 is patterned by using a photolithograph process of a photoresist (not shown). Also, the hard mask 202 may be used as an ion implantation barrier while a subsequent ion implantation process is performed.

The material of the hard mask 202 is selected depending on the material of the substrate 200. When the substrate 200 is a silicon substrate or a polysilicon layer, the hard mask 202 may be formed of an amorphous carbon, a nitride material or an oxide material.

Also, a subsequent ion implantation process affects the hard mask 202, and the thickness of the hard mask 202 may be larger in length than the depth of the ion implantation (as shown in FIG. 3C). Therefore, the hard mask 202 may prevent the ion implantation on the surfaces of the substrate 200 other than in areas of the first pattern 201A and the second pattern 201B during the ion implantation process. Here, any active region of the substrate is prevented from the impurity implantation.

Referring to FIG. 2B, an etch target layer 203 is formed over the resultant structure including the first pattern 201A, the second pattern 201B and the hard mask 202. The etch target layer 203 may be formed of a conductive material, a metal or a dielectric material.

According to an example, the etch target layer 203 is formed of a silicon layer. The etch target layer 203 is formed of a polysilicon layer. Particularly, the polysilicon layer may include an N-type impurity doped polysilicon layer or an undoped polysilicon layer. Since an N-type impurity may include phosphorus (P) and arsenic (As), an etch selectivity may be maximized when the plasma etch-back process is subsequently performed.

The etch target layer 203 is formed to gap-fill the first pattern 201A and the second pattern 201B. When the substrate 200 is the silicon substrate and the etch target layer 203 is the polysilicon layer, an insulation layer formed of an oxide material or a nitride material may be formed over the substrate 200 before the etch target layer 203 is formed. Although not shown in FIG. 2B, a planarization process may be further performed onto the etch target layer 203 so that the etch target layer 203 remains, for example, within the first pattern 201A and the second pattern 201B only.

Referring to FIG. 2C, a first ion implantation process 204 is performed. Since the hard mask 202 is used as an ion implantation barrier, the first ion implantation process 204 is performed onto the etch target layer 203 formed in the first pattern 201A and the second pattern 201B. That is, the hard mask 202 may prevent the ion implantation on the surfaces of the substrate 200 other than areas for the first pattern 201A and the second pattern 201B. The first ion implantation process 204 is performed to implant impurities to a first desired depth. Here, the first ion implantation process 204 may be performed through the hard mask 202, and the first depth may be the same as the thickness of the hard mask 202 or less. Also, the implantation energy of impurities used in the ion implantation process 204 is adjusted so that the surfaces of the substrate 200 below the hard mask 202 are not subjected to the ion-implantation.

First impurity regions 205A and 205B having a desired depth (that is, a desired range of projection (Rp1)) are formed in the etch target layer 203 by the first ion implantation process 204. Regions above or below the first impurity regions 205A and 205B in the etch target layer 203 are not subjected to ion-implantation. The depth (Rp1) of the impurity region 205A formed in the first pattern 201A is the same as that of the impurity region 205B formed in the second pattern 201B.

A thermal treatment process may be further performed to activate the impurities implanted by the first ion implantation process 204. Thus, the first impurity regions 205A and 205B may be uniformly formed.

When the etch target layer 203 is an undoped polysilicon layer or an N-type impurity doped polysilicon layer, P-type impurities are implanted during the first ion implantation process 204. The P-type impurities include boron. A doping source of the P-type impurities may include B and BF₂. The first impurity regions 205A and 205B include a P-type impurity doped polysilicon layer. A dopant dose of the first ion implantation process 204 ranges from approximately 2×10¹⁵ atoms/cm² to approximately 1×10¹⁷ atoms/cm². Also, as the dopant dose of the first ion implantation process 204 is increased, the function of the first impurity regions 205A and 205B as the etch stop barrier gets stronger.

Here, according to an example, when the etch target layer 203 is the N-type impurity doped polysilicon layer, a part of the N-type impurity doped polysilicon layer is changed into the P-type impurity doped polysilicon layer by performing the first ion implantation process 204.

Referring to FIG. 2D, a first plasma etch process 206 is performed to the etch target layer 203. The first plasma etch process 206 may include an etch-back process. The first plasma etch process 206 of the etch target layer 203 is stopped at the first impurity regions 205A and 205B. Then, parts of the etch target layer 203 below the first impurity regions 205A and 205B remain as first etch target patterns 203A.

When the etch target layer 203 is the N-type impurity doped polysilicon layer and the first impurity regions 205A and 205B are the P-type impurity doped polysilicon layer, the first plasma etch process 206 is performed by using the plasma including a halogen such as chlorine (Cl), bromine (Br) or fluorine (F).

While the first plasma etch process 206 is performed, etching rate of the etch target layer 203 formed in the second pattern 201B is faster than that of the etch target layer 203 formed in the first pattern 201A due to the larger width of the second pattern 201B. However, the etching rate of the N-type impurity doped polysilicon layer is different that of the P-type impurity doped polysilicon layer. The etching rate of the N-type impurity doped polysilicon layer is at least two times faster than that of the P-type impurity doped polysilicon layer. That is, the N-type impurity doped polysilicon layer may be selectively etched by using the P-type impurity doped polysilicon layer as an etch stop barrier. Therefore, etch uniformity of the first etch target patterns 203A may be secured. Specifically, the first etch target patterns 203A may be secured although the first pattern 201A and the second pattern 201B have different widths and different depths.

Referring to FIG. 2E, a second ion implantation process 207 is performed. Since the hard mask 202 is used as an ion implantation barrier, the second ion implantation process 207 is performed on the etch target patterns 203A of the first pattern 201A and the second pattern 201B. That is, the hard mask 202 may prevent the ion implantation onto the surfaces of the substrate 200 other than areas of the first pattern 201A and the second pattern 201B. The second ion implantation process 207 is performed to implant impurities to a second desired depth. Here, the hard mask 202 is also subject to the second ion implantation process 207, and the second depth is selected to be the same as the thickness of the hard mask 202 or less. Also, the implantation energy of the second ion implantation process 207 is adjusted so that the surfaces of the substrate 200 below the hard mask 202 are not implanted.

A second depth (Rp2) of the second ion implantation process 207 is determined for the first etch target patterns 203A based on the first projection of range Rp1 of the first ion implantation process 204. That is, the second projection of range Rp2 is located below the first projection of range Rp1. By breaking up the ion implantation into two stages (that is, first and second ion implantation stages), where the second ion implantation is able to implant ions at a deeper depth after the first ion implantation and removal of the etch target layer on top of the first impurity region 205A, hard mask 202 may prevent the ion implantation on the surfaces of the substrate 200 other than areas of the first pattern 201A and the second pattern 201B during the ion implantation process even though the thickness of the hard mask 202 is not great.

Second impurity regions 208A and 208B are formed in the first etch target patterns 203A by the second ion implantation process 207. Regions above and below the second impurity regions 208A and 208B in the first etch target patterns 203A are not subjected to ion-implantation. The depth (Rp2) of the impurity region 208A formed in the first pattern 201A is the same as that of the impurity region 208B formed in the second pattern 201B.

A thermal treatment process may be further performed to activate the impurities implanted by the second ion implantation process 207. Thus, the second impurity regions 208A and 208B may be uniformly formed.

When the first etch target patterns 203A is an undoped polysilicon layer or an N-type impurity doped polysilicon layer, P-type impurities are implanted during the second ion implantation process 207. The P-type impurities include boron. A doping source of the P-type impurities may include B and BF₂. The second impurity regions 208A and 208B include a P-type impurity doped polysilicon layer. A dopant dose of the second ion implantation process 207 ranges from approximately 2×10¹⁵ atoms/cm² to approximately 1×10¹⁷ atoms/cm². Also, as the dopant dose of the second ion implantation process 207 is increased, the function of the second impurity regions 208A and 208B as the etch stop barrier gets stronger.

Here, according to an example, when the first etch target patterns 203A is the N-type impurity doped polysilicon layer, a part of the N-type impurity doped polysilicon layer is changed into the P-type impurity doped polysilicon layer by performing the second ion implantation process 207.

Referring to FIG. 2F, a second plasma etch process 209 is performed to the first etch target patterns 203A. The second plasma etch process 209 may include an etch-back process. Here, before the first etch target patterns 203 are etched, the first impurity regions 205A and 205B are removed. The second plasma etch process 209 of the first etch target patterns 203A is stopped at the second impurity regions 208A and 208B. Then, parts of the first etch target patterns 203A below the second impurity regions 208A and 208B remain as second etch target patterns 203B.

When the first etch target patterns 203A are the N-type impurity doped polysilicon layer and the second impurity regions 208A and 208B are the P-type impurity doped polysilicon layer, the second plasma etch process 209 is performed by using the plasma including a halogen such as chlorine (Cl), bromine (Br) or fluorine (F).

While the second plasma etch process 209 is performed, etching rate of the first etch target patterns 203A formed in the second pattern 201B are faster than that of the first etch target patterns 203A formed in the first pattern 201A due to the larger width of the second pattern 201B. However, the etching rate of the N-type impurity doped polysilicon layer is different that of the P-type impurity doped polysilicon layer. The etching rate of the N-type impurity doped polysilicon layer is at least two times faster than that of the P-type impurity doped polysilicon layer. That is, the N-type impurity doped polysilicon layer may be selectively etched by using the P-type impurity doped polysilicon layer as an etch stop barrier. Therefore, etch uniformity of the second etch target patterns 203B may be secured. Specifically, the second etch target patterns 203B may be secured although the first pattern 201A and the second pattern 201B have different widths and different depths.

In accordance with the above-described second embodiment of the present invention, the first plasma etch process 206 and the second plasma etch process 209 are performed uniformly because the first plasma etch process 206 is stopped at the first impurity regions 205A and 205B, and the second plasma etch process 209 is stopped at the second impurity regions 208A and 208B. Although the etching rate of the etch target layer 203 formed in the second pattern 201B is faster than that of the etch target layer 203 formed in the first pattern 201A due to the micro-loading, the etch target layer 203 is uniformly etched by using the first impurity regions 205A and 205B as the first etch stop barrier, and the first etch target patterns 203A is uniformly etched by using the second impurity regions 208A and 208B as the second etch stop barrier.

In accordance with the embodiments of the present invention, appropriate etch uniformity of the plasma etch process may be obtained by using the impurity region formed in the etch target layer as the etch stop barrier.

Furthermore, while the etch target layer is formed of a polysilicon layer in the semiconductor device, using different etch rates of impurities according to the types of the impurities, the etch uniformity of the plurality patterns having different widths and different depths may be obtained.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device comprising:
forming a plurality of patterns;
forming an etch target layer to gap-fill the plurality of patterns;
forming an impurity region in the etch target layer; and
performing an etch-back process on the etch target layer using the impurity region as an etch stop barrier.

2. The method of claim 1, wherein the plurality of patterns are formed to have different widths, respectively, and different depths, respectively.

3. The method of claim 1, wherein the plurality of patterns are formed to have the same width and the same depth.

4. The method of claim 1, wherein the forming of the impurity region includes performing an ion implantation process.

5. The method of claim 1, wherein the forming of the impurity region includes implanting an impurity into the etch target layer.

6. The method of claim 5, wherein the impurity includes a P-type impurity.

7. The method of claim 6, wherein the etch target layer includes an undoped material or an N-type impurity doped material.

8. The method of claim 6, wherein the P-type impurity includes boron.

9. The method of claim 1, wherein the etch target layer includes a silicon layer.

10. The method of claim 1, wherein the performing of the etch-back process includes using a plasma.

11. The method of claim 1, wherein the forming of the plurality of patterns includes using a hard mask as an etch barrier in forming the plurality of patterns and the performing of the etch-back process includes performing an etch-back process using the hard mask.

12. The method of claim 11, wherein, in length, the thickness of the hard mask is less than the depth that the impurity region lies from the top surface of the hard mask.

13. A method for fabricating a semiconductor device comprising:
forming a plurality of patterns;
forming an etch target layer to gap-fill the plurality of patterns;
forming a first impurity region in the etch target layer;
performing a first etch-back process on the etch target layer using the first impurity region as a first etch stop barrier;
forming a second impurity region in the remaining etch target layer; and
performing a second etch-back process on the remaining etch target layer using the second impurity region as a second etch stop barrier.

14. The method of claim 13, wherein the plurality of patterns are formed to have different widths, respectively, and different depths, respectively.

15. The method of claim 13, wherein the forming of the first impurity region and the forming of the second impurity region each include performing an ion implantation process.

16. The method of claim 13, wherein the forming of the first impurity region includes implanting an impurity into the etch target layer and the forming of the second impurity region includes implanting the impurity into the remaining etch target layer.

17. The method of claim 16, wherein the impurity includes a P-type impurity.

18. The method of claim 17, wherein the etch target layer includes an undoped material and an N-type impurity doped material.

19. A method for fabricating a semiconductor device comprising:
forming a plurality of patterns;
forming a polysilicon layer to gap-fill the plurality of patterns;
forming a P-type impurity region in the polysilicon layer; and
performing a plasma etch-back process on the polysilicon layer using the P-type impurity region as an etch stop barrier.

20. The method of claim 19, wherein the plurality of patterns are formed to have different widths, respectively, and different depths, respectively.
